(19) United States
(12) Patent Application Publication
(10) Pub. No.: US 2026/0305212 A1
(43) Pub. Date: Oct. 1, 2026

(54) STOCK ROLL FOR PROTECTIVE FILM TRANSFER, PROTECTIVE FILM ARRANGING METHOD, AND CHIP MANUFACTURING METHOD

(71) Applicant: DISCO CORPORATION, Tokyo (JP)

(72) Inventors: Tomohiro Kaneko, Tokyo (JP); Masamitsu Kimura, Tokyo (JP); Shingo Motoike, Tokyo (JP)

(21) Appl. No.: 19/553,951

(22) Filed: Mar. 2, 2026

(30) Foreign Application Priority Data
Mar. 31, 2025 (JP) 2025-058045

(51) Int. Cl. H10P 54/92; C08J 5/18; C08J 7/04; H10P 54/94; H10P 58/00; H10P 54/20; H10P 54/40

(52) U.S. Cl. CPC H10P 54/92; C08J 5/18; C08J 7/0427; H10P 54/94; H10P 58/00; C08J 2329/04; H10P 54/20; H10P 54/40

(57) ABSTRACT

Provided is a stock roll for protective film transfer configured by a layered structure being wound, the layered structure including a sheet and a protective film applied to one surface of the sheet, in which the protective film is formed into a semi-cured state in which the protective film can be transferred to an object to be processed.

### BACKGROUND OF THE INVENTION

### Field of the Invention

The present invention relates to a stock roll for protective film transfer configured by a layered structure being wound, the layered structure including a sheet and a protective film applied to one surface of the sheet, a protective film arranging method of arranging a protective film on an object to be processed, and a chip manufacturing method of manufacturing a plurality of chips by dividing a workpiece on which a plurality of devices are formed, along boundaries of the plurality of devices.

### Description of the Related Art

Semiconductor packages including devices such as integrated circuits (ICs) are indispensable components in various electronic appliances including mobile phones and personal computers. This semiconductor package is manufactured through a semiconductor manufacturing process that is largely divided into a front-end process of forming a plurality of devices each including numerous circuit elements on a wafer and a back-end process of manufacturing a semiconductor package from the wafer on which the plurality of devices are formed.

In the back-end process, for example, a semiconductor package is manufactured in the following order. First, a wafer is divided along boundaries of a plurality of devices to manufacture a plurality of dies. Next, the plurality of dies are mounted on a lead frame such that each of the dies is connected to an external electrode. Subsequently, the plurality of dies are sealed by resin to manufacture a semiconductor package substrate. Thereafter, the semiconductor package substrate is divided along boundaries of the plurality of dies (that is, the boundaries of the plurality of devices) to manufacture a plurality of semiconductor packages.

Examples of an apparatus used for dividing a workpiece such as a wafer or a semiconductor package substrate include a cutting apparatus or a laser processing apparatus. In this cutting apparatus, for example, a workpiece is divided by a rotating circular ring-shaped cutting blade being caused to cut into the workpiece. Further, in the laser processing apparatus, for example, the workpiece is divided by laser ablation being caused to occur by application of a laser beam having a wavelength absorbable by the material of the workpiece to the workpiece.

However, causing a cutting blade to cut into a workpiece sometimes results in a burr (specifically, a pointed portion generated due to local plastic deformation) being formed in the workpiece. Moreover, when laser ablation is caused to occur in the workpiece, debris (specifically, a melted portion of the workpiece or a portion obtained by solidification of the melted portion) may scatter and adhere to the workpiece in some cases.

In these cases, the quality of the chips such as the dies or the semiconductor packages manufactured by the workpiece being divided may decline. In view of these points, it has been proposed to arrange a protective film on the workpiece prior to dividing the workpiece, to restrain burrs from being formed or debris from adhering to the workpiece (see, for example, Japanese Patent Laid-open No. 2019-36660 and Japanese Patent Laid-open No. 2004-188475).

### SUMMARY OF THE INVENTION

A protective film is typically arranged on an object to be processed such as a workpiece by use of a spin coating method. Specifically, when a spin coating method is used to arrange a protective film on an object to be processed, first, a protective film forming agent in liquid form is dropped on the object to be processed. Next, the object to be processed is rotated in such a manner as to be spread the protective film forming agent by action of centrifugal force, and to be covered by the protective film forming agent over its entire area. Subsequently, the protective film forming agent is dried. As a result, a protective film is arranged on the object to be processed.

When the protective film is to be arranged in such a manner, a large amount of the protective film forming agent spills over and falls from the object to be processed, in association with the rotation of the object to be processed. The protective film forming agent that has spilled over and fallen from the object to be processed is in many cases discarded without being reused. Hence, in this case, a far greater amount of protective film forming agent than the amount that is finally used as the protective film must be prepared, thereby increasing the cost.

In view of this, the present invention has an object to provide a stock roll for protective film transfer, a protective film arranging method, and a chip manufacturing method that are capable of reducing the cost used at the time of arranging the protective film on the object to be processed.

Specifically, in accordance with an aspect of the present invention, there is provided a stock roll for protective film transfer configured by a layered structure being wound, the layered structure including a sheet and a protective film applied to one surface of the sheet, in which the protective film is formed into a semi-cured state in which the protective film is able to be transferred to an object to be processed.

Note that, in the stock roll for protective film transfer according to the present invention, the protective film preferably includes a thermal foaming agent that foams by being heated to a temperature equal to or higher than a predetermined temperature and/or active energy ray curable resin or thermosetting resin.

In accordance with another aspect of the present invention, there is provided a protective film arranging method of arranging a protective film on an object to be processed, including applying a protective film forming agent in liquid form to one surface of a sheet, forming the protective film forming agent applied to the one surface of the sheet into a protective film in a semi-cured state, and transferring the protective film to the object to be processed, from the sheet.

Note that the protective film arranging method according to the present invention preferably further includes forming the protective film transferred to the object to be processed, into a fully-cured state.

In accordance with a further aspect of the present invention, there is provided a chip manufacturing method of manufacturing a plurality of chips by dividing a workpiece on which a plurality of devices are formed, along boundaries of the plurality of devices, including preparing a stock roll for protective film transfer configured by a layered structure being wound, the layered structure including a sheet and a protective film in a semi-cured state applied to one surface of the sheet, transferring the protective film to the workpiece from the sheet, and dividing the workpiece into the plurality of chips by processing the workpiece from a side where the protective film is arranged, along the boundaries of the plurality of devices.

In accordance with a still further aspect of the present invention, there is provided a chip manufacturing method of manufacturing a plurality of chips by dividing a workpiece on which a plurality of devices are formed, along boundaries of the plurality of devices, including applying a protective film forming agent in liquid form to one surface of a sheet, forming the protective film forming agent applied to the one surface of the sheet into a protective film in a semi-cured state, transferring the protective film to the workpiece from the sheet, and dividing the workpiece into the plurality of chips by processing the workpiece from a side where the protective film is arranged, along the boundaries of the plurality of devices.

Note that the chip manufacturing method according to the present invention preferably further includes, before dividing the workpiece into the plurality of chips, forming the protective film transferred to the workpiece into a fully-cured state. Further, when the protective film includes a thermal foaming agent that foams by being heated to a temperature equal to or higher than a predetermined temperature, the chip manufacturing method according to the present invention preferably further includes removing the protective film from each of the plurality of chips by heating the protective film remaining in each of the plurality of chips to a temperature equal to or higher than the predetermined temperature to foam.

According to the present invention, the protective film can be transferred to and arranged on the object to be processed, by being formed into a semi-cured state. In this case, compared to the case of using a spin coating method to arrange the protective film on the object to be processed, the amount of raw material (protective film forming agent) of the protective film discarded without being used can be reduced. Hence, the present invention can reduce the cost used at the time of arranging a protective film on an object to be processed.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating an example of a stock roll for protective film transfer;

FIG. 2 is a flowchart schematically illustrating an example of a stock roll preparing method of preparing the stock roll illustrated in FIG. 1;

FIG. 3 is a flowchart schematically illustrating an example of a protective film arranging method of arranging a protective film on an object to be processed, by using the stock roll illustrated in FIG. 1;

FIG. 4A is a plan view schematically illustrating an example of an object to be processed on which a protective film is arranged;

FIG. 4B is a side view schematically illustrating the object to be processed that is illustrated in FIG. 4A;

FIG. 5 is a side view schematically illustrating the manner of performing a transferring step illustrated in FIG. 3;

FIG. 6 is a flowchart schematically illustrating an example of a chip manufacturing method of manufacturing chips from the workpiece illustrated in FIGS. 4A and 4B;

FIG. 7 is a plan view schematically illustrating the manner of performing a dividing step illustrated in FIG. 6;

FIG. 8 is a side view, partly in cross section, schematically illustrating the manner of performing the protective film arranging method by using a transfer apparatus that can perform not only the transferring step illustrated in FIG. 3 but also an applying step and a semi-curing step illustrated in FIG. 2;

FIG. 9 is a flowchart schematically illustrating another example of the chip manufacturing method of manufacturing chips from the workpiece illustrated in FIGS. 4A and 4B;

FIG. 10 is a side view schematically illustrating the manner of performing a full-curing step illustrated in FIG. 9;

FIG. 11 is a flowchart schematically illustrating a further example of the chip manufacturing method of manufacturing chips from the workpiece illustrated in FIGS. 4A and 4B; and

FIG. 12 is a side view schematically illustrating the manner of performing a removing step illustrated in FIG. 11.

### DETAILED DESCRIPTION OF THE PREFERRED EMBODIMENT

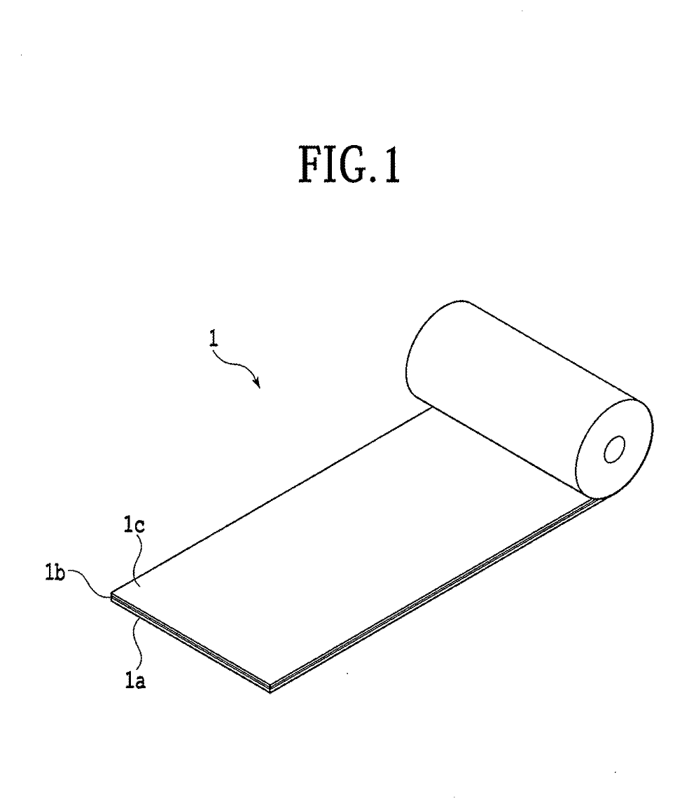

An embodiment of the present invention will be described in detail below with reference to the accompanying drawings. FIG. 1 is a perspective view schematically illustrating an example of a stock roll for protective film transfer (stock roll 1). The stock roll 1 is configured by a layered structure being wound, the layered structure having a rectangular shape whose length is orders of magnitude greater than its width. The layered structure includes, for example, a sheet 1a, a protective film 1b applied to one surface of the sheet 1a, and a release liner 1c provided in such a manner as to sandwich the protective film 1b with the sheet 1a.

The sheet 1a includes, for example, such resin as polyolefin (PO), polyethylene terephthalate (PET), polyvinyl chloride (PVC), or polystyrene (PS). Note that the one surface of the sheet 1a may have an irregular shape to improve the adhesiveness with the protective film 1b. For example, the one surface of the sheet 1a may have greater surface roughness than the other surface.

The protective film 1b includes, for example, resin that polymerizes and cures by energy being applied thereto. Examples of the resin include active energy ray curable resin that polymerizes and cures by being irradiated with active energy rays such as ultraviolet rays, as exemplified by urethane acrylate, epoxy acrylate, or acrylic acrylate, or thermosetting resin that polymerizes and cures by being heated, as exemplified by phenolic resin, epoxy resin, melanin resin, or polyester resin. Further, the protective film 1b may include water-soluble resin such as polyvinyl alcohol (PVA) in place of or in addition to the abovementioned resin.

Further, the protective film 1b may include a foaming agent that foams by energy being applied thereto. Examples of the foaming agent include a thermal foaming agent that foams by being heated to a temperature equal to or higher than a predetermined temperature, as exemplified by a thermally expandable microcapsule, or an active energy ray foaming agent that foams by active energy rays being applied thereto.

Further, the protective film 1b is in a semi-cured state by being subjected to at least one of heating, application of active energy rays, or drying. Note that, in the present specification, the semi-cured state refers to a state of the protective film 1b in which the protective film 1b can be transferred to a transfer target object (hereinafter also referred to as an “object to be processed”) from the sheet 1a. Specifically, the semi-cured state refers to a state in which the protective film 1b does not fall off from the sheet 1a even when being oriented downward after being removed from the release liner 1c, and/or would not be transferred to the object to be processed despite slightly coming into contact with the object to be processed but is transferred to the object to be processed when a pressing force that acts on the protective film 1b and the object to be processed exceeds a threshold.

In other words, in the present specification, the semi-cured state refers to a state that is neither an uncured state nor a fully-cured state. Further, in the present specification, the uncured state is a state in which the protective film 1b would be transferred to the object to be processed, even when the pressing force that acts on the two members is less than the threshold. Further, in the present specification, the fully-cured state is a state in which the protective film 1b would not be transferred to the object to be processed, no matter how great the pressing force that acts on the two members is made. Further, in the present specification, the semi-cured state can be expressed as what is generally called a B-staged state.

The release liner 1c is wound in the stock roll 1 in such a manner that one surface thereof comes into contact with the protective film 1b while the other surface comes into contact with the sheet 1a. Further, the release liner 1c is configured to be easily peeled off from the protective film 1b in the semi-cured state. For example, the release liner 1c includes a base layer and a peel-off layer provided on the protective film 1b side of the base layer.

Note that the base layer includes such resin as polypropylene (PP), polyethylene (PE), or polyethylene terephthalate (PET). Further, the peel-off layer includes, for example, a silicone material such as a fluorine-containing silicone material or a non-silicone material. Note that the stock roll 1 need not include the release liner 1c. In this case, the other surface of the sheet 1a may be subjected to surface treatment to avoid the protective film 1b from being transferred.

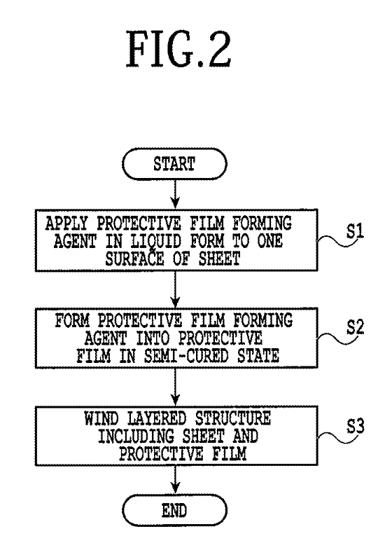

FIG. 2 is a flowchart schematically illustrating an example of a stock roll preparing method of preparing the stock roll 1. In this method, applying a protective film forming agent in liquid form to the one surface of the sheet 1a (applying step S1), forming the protective film forming agent applied to the one surface of the sheet 1a into the protective film 1b in the semi-cured state (semi-curing step S2), and winding a layered structure including the sheet 1a and the protective film 1b (winding step S3) are performed in this order.

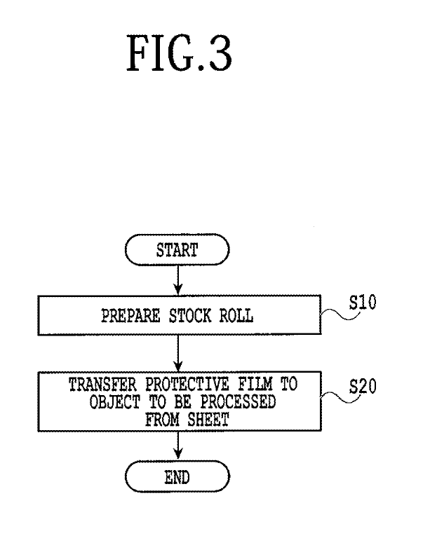

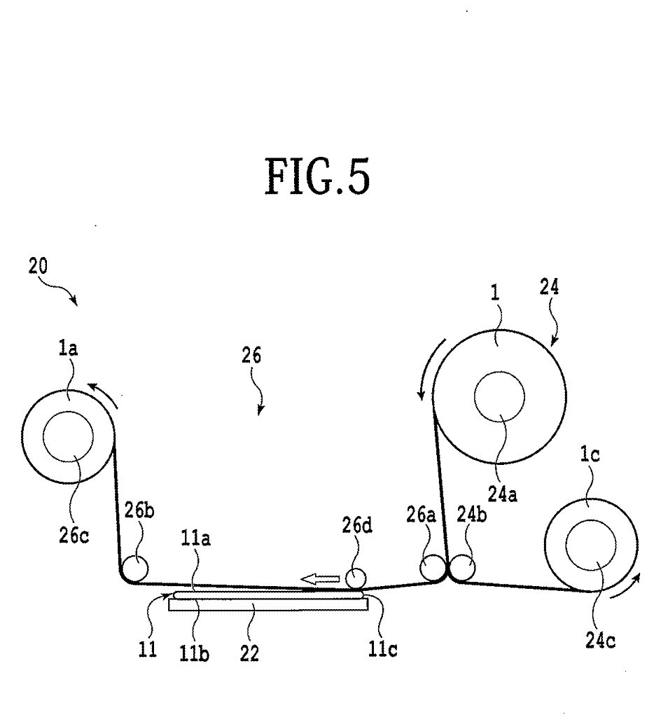

FIG. 3 is a flowchart schematically illustrating an example of a protective film arranging method of arranging a protective film on the object to be processed, by use of the stock roll 1. In this method, first, the stock roll 1 is prepared (preparing step S10). In the preparing step S10, for example, the stock roll 1 that has been prepared in accordance with the stock roll preparing method illustrated in FIG. 2 or that has been transferred (for example, purchased) from a third party is arranged at a predetermined position (a pay-out roller 24a included in a supply section 24 of a transfer apparatus 20 described later (see FIG. 5)).

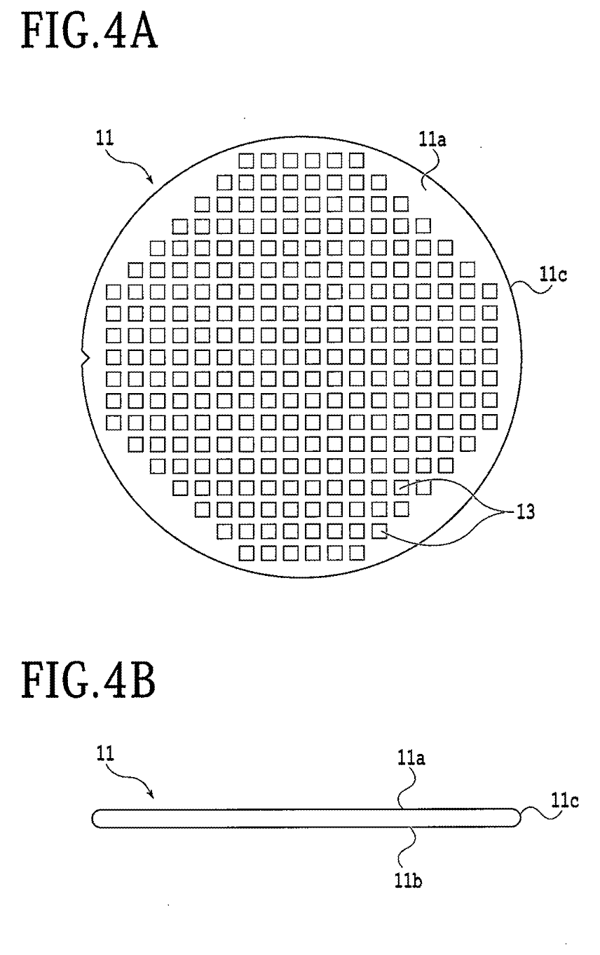

After the preparing step S10 has been carried out, the protective film 1b is partially transferred to the object to be processed, from the sheet 1a (transferring step S20). FIG. 4A is a plan view schematically illustrating an example of an object to be processed (workpiece 11) to which the protective film 1b is transferred, while FIG. 4B is a side view schematically illustrating the workpiece 11.

The workpiece 11 has a face side 11a and a reverse side 11b that are substantially parallel to each other and is a wafer made of silicon (Si), for example. On the face side 11a of the workpiece 11, a plurality of devices 13 are provided. The devices 13 may include, for example, semiconductor elements for use in ICs, semiconductor memories, or complementary metal oxide semiconductor (CMOS) image sensors.

The plurality of devices 13 are provided in a matrix pattern. That is, the boundaries of the plurality of devices 13 extend in a grid pattern. Further, portions that constitute the boundaries and extend linearly are also called projected dicing lines. Further, an outer peripheral edge portion of the workpiece 11 is beveled. In other words, a side surface 11c of the workpiece 11 is curved in such a manner as to protrude outwardly.

Note that there are no limitations on the material, shape, structure, size, or the like of the workpiece 11. The workpiece 11 may, for example, be a wafer made of any semiconductors other than silicon (for example, silicon carbide (SiC), gallium nitride (GaN), or the like). Similarly, there are also no limitations on the type, quantity, shape, structure, size, layout, or the like of the plurality of devices 13.

Further, the workpiece 11 may be integrated with a ring frame (not illustrated) via a support member (not illustrated) including an adhesive layer affixed to the reverse side 11b thereof. Alternatively, the workpiece 11 may be integrated with a ring frame via a support member not including an adhesive layer thermocompression-bonded to the reverse side 11b thereof.

FIG. 5 is a side view, partly in cross section, schematically illustrating the manner of performing the transferring step S20. Note that, for the sake of convenience, in the following description, the right side on the sheet of paper indicating FIG. 5 is described as the front side, that is, the left side as the rear side, and the upper side as the higher side, that is, the lower side as the lower side.

The transferring step S20 is performed with use of the transfer apparatus 20. The transfer apparatus 20 has a chuck table 22 for holding the workpiece 11. The chuck table 22 has, for example, a disk-shaped frame body made of ceramics or the like and a disk-shaped porous plate fixed to a recess formed on an upper surface side of the frame body.

Moreover, the frame body of the chuck table 22 is provided with a fluid channel that is open at a bottom surface of the recess and that is connected to a suction source (not illustrated) and a fluid supply source (not illustrated) via a valve (not illustrated) or the like. Note that the suction source includes an ejector, for example. Further, the fluid supply source includes, for example, a tank for storing high pressure gas, a filter for removing contaminants that have been mixed to the gas supplied from the tank, and a regulator for adjusting the pressure of the gas supplied from the tank.

Further, when the suction source communicating with the fluid channel formed in the frame body is operated in a state in which the workpiece 11 is placed on the chuck table 22, the pressure in the fluid channel becomes negative. As a result, suction force acts on the workpiece 11 loaded to the chuck table 22, via the porous plate. That is, the workpiece 11 is held under suction on the chuck table 22.

Further, when the fluid supply source communicating with the fluid channel formed in the frame body is operated in a state in which the workpiece 11 is held on the chuck table 22, the pressure in the fluid channel returns to ordinary pressure. As a result, suction force no longer acts on the workpiece 11 loaded to the chuck table 22, via the porous plate. That is, the workpiece 11 is merely placed on the chuck table 22.

Further, the chuck table 22 is coupled to a horizontal direction moving mechanism (not illustrated). The horizontal direction moving mechanism includes, for example, a ball screw and a motor connected to the ball screw. Further, when the horizontal direction moving mechanism is operated, the chuck table 22 moves along the horizontal direction. For example, when the horizontal direction moving mechanism is operated, the chuck table 22 moves between a loading/unloading position and a transfer position.

Note that the loading/unloading position is a position of the chuck table 22 where the loading of the workpiece 11 to the chuck table 22 and unloading of the workpiece 11 from the chuck table 22 can easily be performed. Further, the transfer position is a position of the chuck table 22 where the protective film 1b can be transferred to the workpiece 11 held on the chuck table 22, from the sheet 1a paid out from the stock roll 1.

On the upper side of the chuck table 22 positioned at the transfer position, the supply section 24 for exposing and supplying the protective film 1b applied to the one surface of the sheet 1a and a transfer section 26 for transferring the protective film 1b to the workpiece 11 from the sheet 1a are provided.

The supply section 24 includes the pay-out roller 24a for paying out the layered structure including the sheet 1a, the protective film 1b, and the release liner 1c from the stock roll 1. Note that the pay-out roller 24a is positioned on the front side of the chuck table 22 positioned at the transfer position in plan view. On the lower side of the pay-out roller 24a, a guide roller 24b is provided. The other surface of the release liner 1c included in the layered structure paid out from the pay-out roller 24a comes into contact with the guide roller 24b.

On the front side of the guide roller 24b, a release liner collecting roller 24c for collecting the release liner 1c is provided. To the release liner collecting roller 24c, a distal end of the release liner 1c is fixed. When the release liner collecting roller 24c is rotated, the release liner 1c heading forward from the guide roller 24b is rolled up by the release liner collecting roller 24c.

The transfer section 26 includes a guide roller 26a provided on the rear side of the guide roller 24b in a manner of approaching the guide roller 24b. The other surface of the sheet 1a included in the layered structure paid out from the pay-out roller 24a comes into contact with the guide roller 26a. On the rear side of the guide roller 26a, a guide roller 26b positioned on the rear side of the chuck table 22 positioned at the transfer position in plan view is provided. The other surface of the sheet 1a drawn out from the guide roller 26a toward the rear side comes into contact with the guide roller 26b.

On the upper side of the guide roller 26b, a sheet collecting roller 26c for collecting the sheet 1a in which the protective film 1b that has not been transferred to the workpiece 11 remains on the one surface thereof is provided. To the sheet collecting roller 26c, a distal end of the sheet 1a is fixed. When the sheet collecting roller 26c is rotated, the sheet 1a heading upward from the guide roller 26b is rolled up by the sheet collecting roller 26c.

Further, a presser roller 26d is provided between the two guide rollers 26a and 26b. The presser roller 26d is connected to a moving mechanism (not illustrated). The moving mechanism includes, for example, a timing belt and a motor connected to the timing belt. When the moving mechanism is operated, the presser roller 26d moves in such a manner as to cycle through a standby position, a transfer start position, and a transfer end position.

Note that the standby position is a position of the presser roller 26d where the presser roller 26d does not come into contact with the sheet 1a (specifically, a position on the rear side of the guide roller 26a but on the front side of the guide roller 26b in plan view and on the upper side of the two rollers). Further, the transfer start position is a position of the presser roller 26d where the protective film 1b can be pressed against a front end of the workpiece 11 held on the chuck table 22 via the sheet 1a. The transfer end position is a position of the presser roller 26d where the protective film 1b can be pressed against a rear end of the workpiece 11 held on the chuck table 22 via the sheet 1a.

In performing the transferring step S20 in the transfer apparatus 20, first, the chuck table 22 is positioned at the loading/unloading position. Next, the workpiece 11 is loaded to the chuck table 22 in such a manner that the face side 11a faces upward. Subsequently, the workpiece 11 is held on the chuck table 22.

Thereafter, the chuck table 22 is positioned at the transfer position. Then, the presser roller 26d is moved from the standby position to pass through the transfer start position and the transfer end position and eventually return to the standby position. As a result, the protective film 1b is pressed against the workpiece 11 via a circular region included in the sheet 1a. Consequently, a portion of the protective film 1b that is applied to the region is transferred to the face side 11a of the workpiece 11.

Note that, in performing the transferring step S20 in the transfer apparatus 20, the chuck table 22 may be moved in place of or in addition to the presser roller 26d being moved, to transfer the portion of the protective film 1b that is applied to the circular region included in the sheet 1a to the face side 11a of the workpiece 11 via the region. That is, at the time of transfer, the chuck table 22 may be moved in a state in which the protective film 1b is pressed against the face side 11a of the workpiece 11 via the sheet 1a by the presser roller 26d.

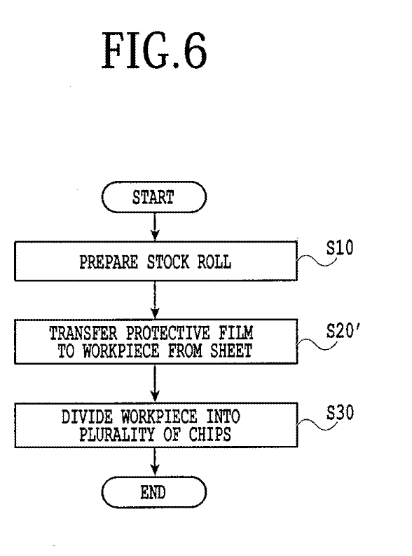

FIG. 6 is a flowchart schematically illustrating an example of a chip manufacturing method of manufacturing chips from the workpiece 11. In this method, first, the preparing step S10 is performed, and then the protective film 1b is partially transferred to the workpiece 11 from the sheet 1a (transferring step S20’). The transferring step S20’ is performed in a manner similar to that of the transferring step S20 illustrated in FIG. 5, for example.

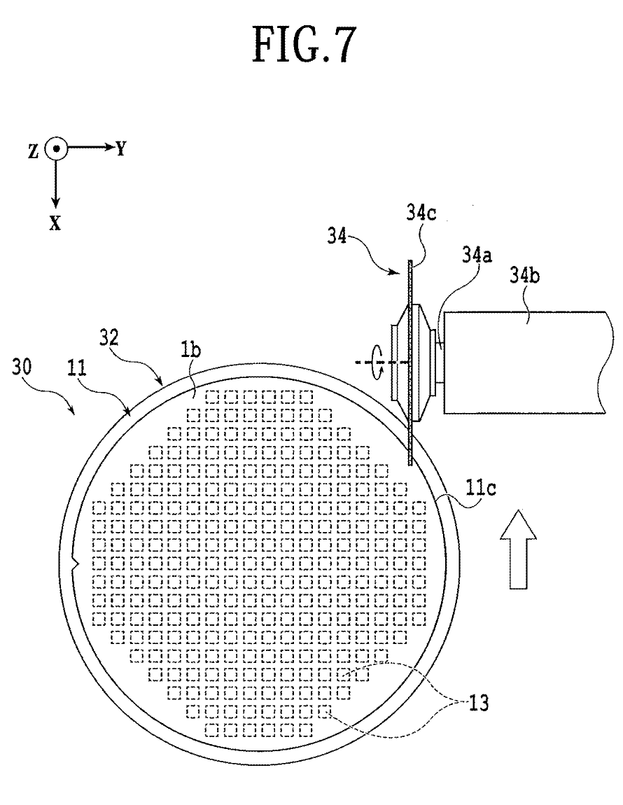

After the transferring step S20’ has been carried out, the workpiece 11 is divided into a plurality of chips (dividing step S30). FIG. 7 is a plan view schematically illustrating the manner of performing the dividing step S30. Note that a direction (X direction) indicated by an arrow X and a direction (Y direction) indicated by an arrow Y illustrated in FIG. 7 are directions orthogonal to each other on a horizontal plane, and a direction (Z direction) indicated by an arrow Z is a direction (vertical direction) orthogonal to each of the X direction and the Y direction.

The dividing step S30 is performed with use of a cutting apparatus 30. The cutting apparatus 30 has a chuck table 32 for holding the workpiece 11. The chuck table 32 has, for example, a structure similar to that of the chuck table 22 illustrated in FIG. 5, and can hold the workpiece 11 by suction force acting thereon.

Further, the chuck table 32 is coupled to an X direction moving mechanism (not illustrated). The X direction moving mechanism includes, for example, a ball screw and a motor connected to the ball screw. When the X direction moving mechanism is operated, the chuck table 32 moves along the X direction.

In addition, the chuck table 32 is coupled to a rotation mechanism (not illustrated). The rotation mechanism includes, for example, a shaft, a pulley coupled to the shaft, and a motor for rotating the pulley. When the rotation mechanism is operated, the chuck table 32 rotates about a straight line passing through the center of the rotation mechanism and extending along the Z direction, as the rotational axis.

The cutting apparatus 30 also includes a cutting unit 34 disposed above the chuck table 32. The cutting unit 34 includes a spindle 34a extending along the Y direction. The spindle 34a is housed in a housing 34b except a distal end portion thereof. In the housing 34b, a motor (not illustrated) connected to a proximal end portion of the spindle 34a is also housed, and is operated to rotate the spindle 34a about a straight line extending along the Y direction, as the rotational axis.

To the distal end portion of the spindle 34a, a cutting blade 34c is mounted. The cutting blade 34c has a circular ring-shaped cutting edge including a binding material made of metal, ceramics, resin, or the like and abrasive grains of diamond or the like dispersed in the binding material.

Further, the cutting unit 34 is coupled to a Y direction moving mechanism (not illustrated) and a Z direction moving mechanism (not illustrated). Each of the Y direction moving mechanism and the Z direction moving mechanism includes, for example, a ball screw and a motor connected to the ball screw. When the Y direction moving mechanism is operated, the cutting unit 34 moves along the Y direction, and, when the Z direction moving mechanism is operated, the cutting unit 34 moves along the Z direction.

When the dividing step S30 is to be carried out in the cutting apparatus 30, first, the chuck table 32 is moved along the X direction in such a manner as to be separated from the cutting blade 34c in plan view. Next, the workpiece 11 is loaded to the chuck table 32 such that the protective film 1b faces upward. Note that, to the reverse side 11b of the workpiece 11, a support member is firmly fixed prior to the loading of the workpiece 11 to the chuck table 32. Further, the workpiece 11 may be integrated with the ring frame via the support member.

Next, the workpiece 11 is held on the chuck table 32 via the support member. Subsequently, the chuck table 32 is rotated such that the projected dicing lines become parallel to the X direction. Then, the cutting unit 34 is moved along the Y direction such that one of the projected dicing lines is positioned in the X direction as viewed from the cutting blade 34c in plan view.

Thereafter, the cutting unit 34 is moved along the Z direction such that a lower end of the cutting blade 34c is positioned at a height corresponding to the support member. Then, the chuck table 32 is moved along the X direction in such a manner that the cutting blade 34c is caused to cut into the protective film 1b and the workpiece 11, while the spindle 34a is rotated together with the cutting blade 34c.

As a result, the workpiece 11 is divided along the projected dicing line. Further, the abovementioned operation is repeated until the workpiece 11 is divided along all of the boundaries of the plurality of devices 13. Consequently, a plurality of chips are manufactured from the workpiece 11.

In the embodiment described above, the protective film 1b can be transferred to and arranged on the workpiece 11, by being formed into the semi-cured state. In this case, compared to the case where the protective film 1b is arranged on the workpiece 11 with use of the spin coating method, the amount of raw material (protective film forming agent) of the protective film 1b that is discarded without being used can be reduced. Hence, the abovementioned embodiment can reduce the cost used at the time of arranging the protective film 1b on the workpiece 11.

Note that the abovementioned embodiment is one mode of the present invention; the present invention is not limited to the embodiment described above.

For example, the stock roll of the present invention may be wound in such a manner that the sheet 1a is positioned on the innermost side, that is, the release liner 1c is positioned on the outermost side, instead of being wound such that the sheet 1a is positioned on the outermost side, that is, the release liner 1c is positioned on the innermost side. Further, when the stock roll of the present invention does not include the release liner 1c, the sheet 1a may be wound such that the other surface is positioned on the inner side instead of the one surface to which the protective film 1b is applied being positioned on the inner side.

Further, the protective film arranging method according to the present invention may include a transferring step S20 that is performed with use of a transfer apparatus having a structure different from that of the transfer apparatus 20. Examples of such a transfer apparatus include a transfer apparatus capable of making the pressure in a space on the one surface side of the sheet 1a lower than the pressure in a space on the other surface side in a state in which the protective film 1b applied to the one surface of the sheet 1a and the face side 11a of the workpiece 11 are brought close to each other. That is, in the transferring step S20, the protective film 1b may be transferred to the workpiece 11 by being pressed against the face side 11a of the workpiece 11 via the sheet 1a with use a pressure difference between the two spaces.

Further, the protective film arranging method according to the present invention may be performed with use of a transfer apparatus capable of carrying out not only the transferring step S20 but also the applying step S1 and the semi-curing step S2.

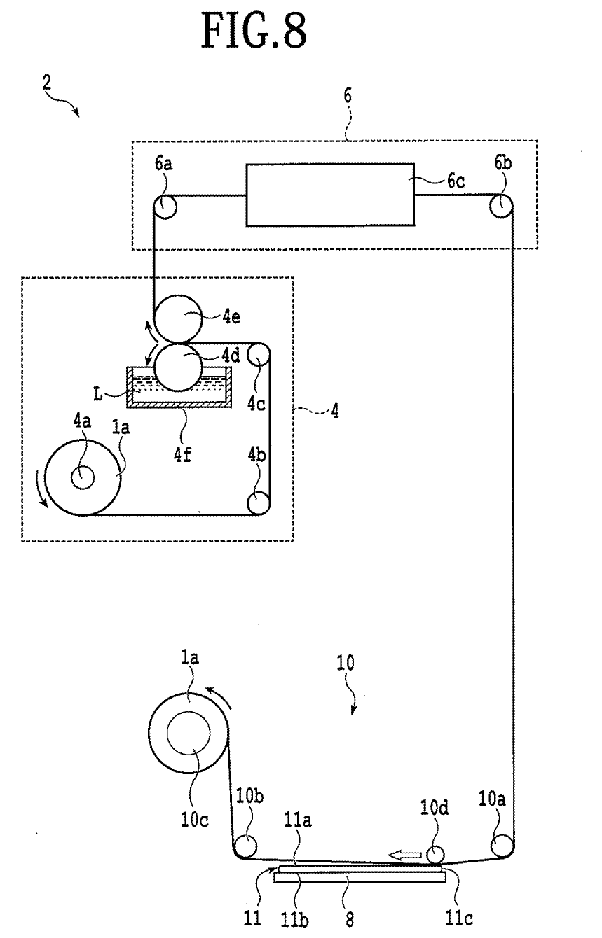

FIG. 8 is a side view, partly in cross section, schematically illustrating the manner of carrying out the protective film arranging method in an example of such a transfer apparatus (transfer apparatus 2). Note that, for the sake of convenience, in the following description, the right side on the sheet of paper illustrating FIG. 8 is described as the front side, that is, the left side as the rear side, and the upper side as the higher side, that is, the lower side as the lower side.

The transfer apparatus 2 includes an applying section 4 for carrying out the applying step S1, a semi-curing section 6 for carrying out the semi-curing step S2, and a chuck table 8 and a transfer section 10 both for carrying out the transferring step S20.

The applying section 4 has a pay-out roller 4a around which the sheet 1a is wound. When the pay-out roller 4a is rotated, the sheet 1a is paid out. On the front side of the pay-out roller 4a, a guide roller 4b is provided. The one surface of the sheet 1a that is paid out by the pay-out roller 4a being rotated comes into contact with the guide roller 4b.

On the upper side of the guide roller 4b, a guide roller 4c is provided. The one surface of the sheet 1a heading upward from the guide roller 4b comes into contact with the guide roller 4c. On the rear side of the guide roller 4c, an applying roller 4d and a presser roller 4e are provided in such a manner as to approach each other and line up in the vertical direction. Note that a width of each of the applying roller 4d and the presser roller 4e (the length in the depth direction on the sheet of paper illustrating FIG. 8) is substantially equal to or greater than the width of the sheet 1a.

Further, the applying roller 4d and the presser roller 4e are arranged such that the two rollers are pressed against each other and a portion of the applying roller 4d near an upper end thereof and a portion of the presser roller 4e near a lower end thereof slightly elastically deform. Further, a lower portion of the applying roller 4d is positioned inside a tank 4f, which is filled with a protective film forming agent L such that the protective film forming agent L at least comes into contact with a lower end of the applying roller 4d.

Note that a surface of the applying roller 4d may have an irregular shape to improve adhesiveness with the protective film forming agent L. When both the applying roller 4d and the presser roller 4e are rotated, the surface of the applying roller 4d is pressed against the one surface of the sheet 1a heading rearward from the guide roller 4c, and the sheet 1a is sent out from the applying roller 4d and the presser roller 4e.

Here, to the surface of the applying roller 4d, the protective film forming agent L scooped up from the tank 4f is attached. Hence, by the surface of the applying roller 4d being pressed against the one surface of the sheet 1a, the protective film forming agent L is applied to the one surface of the sheet 1a. That is, the applying step S1 is carried out.

The semi-curing section 6 includes a guide roller 6a provided above the presser roller 4e. The other surface of the sheet 1a that is sent out by both the applying roller 4d and the presser roller 4e being rotated comes into contact with the guide roller 6a. On the front side of the guide roller 6a, a guide roller 6b is provided. The other surface of the sheet 1a heading forward from the guide roller 6a comes into contact with the guide roller 6b.

Further, a semi-curing unit 6c for forming the protective film forming agent L applied to the one surface of the sheet 1a into the protective film 1b in the semi-cured state is provided between the pair of guide rollers 6a and 6b. The semi-curing unit 6c includes, for example, at least one of a heater, an active energy ray irradiator, or a dehydrator.

When the semi-curing unit 6c is operated, part of resin included in the protective film forming agent L applied to the one surface of the sheet 1a polymerizes and cures and/or is reduced in the amount of water contained, so that the protective film forming agent L is formed into the protective film 1b in the semi-cured state. That is, the semi-curing step S2 is carried out.

The chuck table 8 has a structure similar to that of the chuck table 22 of the transfer apparatus 20 illustrated in FIG. 5. Specifically, the chuck table 8 has, for example, a disk-shaped frame body made of ceramics or the like and a disk-shaped porous plate fixed to a recess formed on an upper surface side of the frame body.

Moreover, the frame body of the chuck table 8 is provided with a fluid channel that is open at a bottom surface of the recess and that is connected to a suction source (not illustrated) and a fluid supply source (not illustrated) via a valve (not illustrated) or the like. Note that the suction source includes an ejector, for example. Further, the fluid supply source includes, for example, a tank for storing high pressure gas, a filter for removing contaminants that have been mixed to the gas supplied from the tank, and a regulator for adjusting the pressure of the gas supplied from the tank.

Further, when the suction source communicating with the fluid channel formed in the frame body is operated in a state in which the workpiece 11 is placed on the chuck table 8, the pressure in the fluid channel becomes negative. As a result, suction force acts on the workpiece 11 loaded to the chuck table 8, via the porous plate. That is, the workpiece 11 is held under suction on the chuck table 8.

Further, when the fluid supply source communicating with the fluid channel formed in the frame body is operated in a state in which the workpiece 11 is held on the chuck table 8, the pressure in the fluid channel returns to ordinary pressure. As a result, suction force no longer acts on the workpiece 11 loaded to the chuck table 8, via the porous plate. That is, the workpiece 11 is merely placed on the chuck table 8.

Further, the chuck table 8 is coupled to a horizontal direction moving mechanism (not illustrated). The horizontal direction moving mechanism includes, for example, a ball screw and a motor connected to the ball screw. When the horizontal direction moving mechanism is operated, the chuck table 8 moves along the horizontal direction. For example, when the horizontal direction moving mechanism is operated, the chuck table 8 moves between a loading/unloading position and a transfer position.

Note that the loading/unloading position is a position of the chuck table 8 where the loading of the workpiece 11 to the chuck table 8 and unloading of the workpiece 11 from the chuck table 8 can easily be performed. Further, the transfer position is a position of the chuck table 8 where the protective film 1b can be transferred to the workpiece 11 held on the chuck table 8 from the sheet 1a.

The transfer section 10 has a structure similar to that of the transfer section 26 of the transfer apparatus 20 illustrated in FIG. 5. Specifically, the transfer section 10 includes a guide roller 10a. The other surface of the sheet 1a heading downward from the guide roller 6b of the semi-curing section 6 comes into contact with the guide roller 10a.

On the rear side of the guide roller 10a, a guide roller 10b positioned on the rear side of the chuck table 8 positioned at the transfer position in plan view is provided. The other surface of the sheet 1a drawn out from the guide roller 10a toward the rear side comes into contact with the guide roller 10b.

On the upper side of the guide roller 10b, a sheet collecting roller 10c for collecting the sheet 1a in which the protective film 1b that has not been transferred to the workpiece 11 remains on the one surface thereof is provided. To the sheet collecting roller 10c, the distal end of the sheet 1a is fixed. When the sheet collecting roller 10c is rotated, the sheet 1a heading upward from the guide roller 10b is rolled up by the sheet collecting roller 10c.

Further, a presser roller 10d is provided between the two guide rollers 10a and 10b. The presser roller 10d is connected to a moving mechanism (not illustrated). The moving mechanism includes, for example, a timing belt and a motor connected to the timing belt. When the moving mechanism is operated, the presser roller 10d moves in such a manner as to cycle through a standby position, a transfer start position, and a transfer end position.

Note that the standby position is a position of the presser roller 10d where the presser roller 10d does not come into contact with the sheet 1a (specifically, a position on the rear side of the guide roller 10a but on the front side of the guide roller 10b in plan view and on the upper side of the two rollers). Further, the transfer start position is a position of the presser roller 10d where the protective film 1b can be pressed against the front end of the workpiece 11 held on the chuck table 8 via the sheet 1a. The transfer end position is a position of the presser roller 10d where the protective film 1b can be pressed against the rear end of the workpiece 11 held on the chuck table 8 via the sheet 1a.

Further, in the transfer apparatus 2, the applying section 4 and the semi-curing section 6 are operated as in the applying step S1 and the semi-curing step S2 illustrated in FIG. 2, and the chuck table 8 and the transfer section 10 are operated as in the transferring step S20 illustrated in FIG, 3, so that the protective film 1b is transferred to the workpiece 11 from the sheet 1a.

Note that, in carrying out the transferring step S20 in the transfer apparatus 2, the chuck table 8 may be moved in place of or in addition to the presser roller 10d being moved, to transfer the portion of the protective film 1b that is applied to a circular region included in the sheet 1a to the face side 11a of the workpiece 11 via the region. That is, at the time of transfer, the chuck table 8 may be moved in a state in which the protective film 1b is pressed against the face side 11a of the workpiece 11 via the sheet 1a by the presser roller 10d.

Further, the chip manufacturing method according to the present invention may include a dividing step S30 that is carried out with use of a cutting apparatus having a structure different from that of the cutting apparatus 30 or a processing apparatus other than the cutting apparatus. Examples of such a processing apparatus include a laser processing apparatus capable of processing a workpiece by applying a laser beam having a wavelength absorbable by the material of the workpiece 11. That is, in the dividing step S30, the workpiece 11 may be divided into a plurality of chips by a laser beam being applied to the workpiece 11 in such a manner that laser ablation occurs along the boundaries of the plurality of devices 13.

Further, the chip manufacturing method according to the present invention may include a dividing step S30 that is carried out with use of two or more types of processing apparatuses. Examples of the two or more types of processing apparatuses include such an apparatus (division initiating point forming apparatus) as a cutting apparatus or a laser processing apparatus capable of forming division initiating points (for example, grooves) in the workpiece 11 and a grinding apparatus capable of grinding the workpiece 11. Further, in the dividing step S30, for example, the workpiece 11 may be divided into a plurality of chips with the division initiating points used as boundaries, by the reverse side 11b of the workpiece 11 being ground with use of the grinding apparatus after the division initiating points have been formed on the face side 11a of the workpiece 11 with use of the division initiating point forming apparatus.

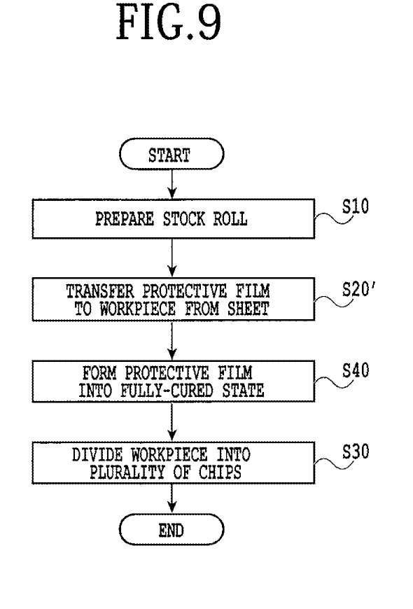

Further, the chip manufacturing method according to the present invention may be a chip manufacturing method including another step in addition to the preparing step S10, the transferring step S20’, and the dividing step S30 illustrated in FIG. 6. For example, the chip manufacturing method according to the present invention may include a full-curing step S40 for forming the protective film 1b into a fully-cured state, after the transferring step S20’ is carried out but before the dividing step S30 is performed, as illustrated in FIG. 9.

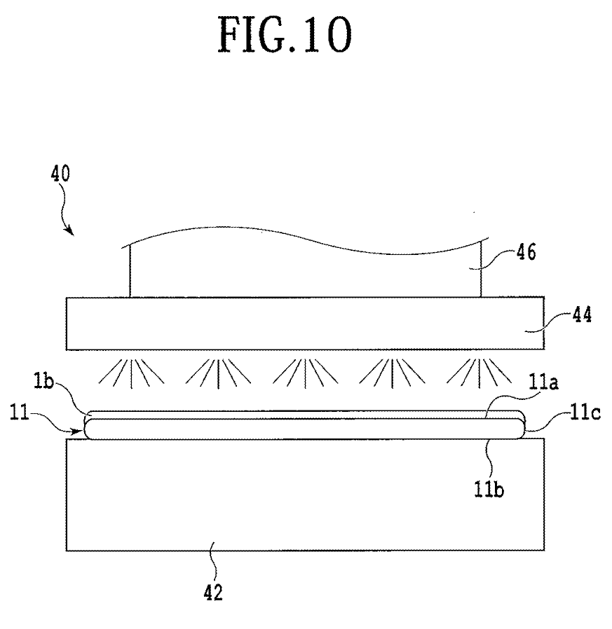

FIG. 10 is a side view schematically illustrating the manner of carrying out the full-curing step S40. The full-curing step S40 is carried out with use of a curing apparatus 40. The curing apparatus 40 includes a table 42 for supporting the workpiece 11. Above the table 42, a full-curing unit 44 is provided.

The full-curing unit 44 includes, for example, at least one of a heater for heating a space on the lower side, an active energy ray irradiator for applying active energy rays such as ultraviolet rays toward the space on the lower side, or a dehydrator for dehydrating the space on the lower side. Further, the full-curing unit 44 is coupled to a lifting/lowering mechanism 46. The lifting/lowering mechanism 46 includes, for example, a ball screw and a motor connected to the ball screw. When the lifting/lowering mechanism 46 is operated, the full-curing unit 44 is lifted or lowered.

In performing the full-curing step S40 in the curing apparatus 40, first, the full-curing unit 44 is lifted in such a manner as to be separated from the table 42. Next, the workpiece 11 is loaded to the table 42 such that the protective film 1b in the semi-cured state faces upward. Subsequently, the full-curing unit 44 is lowered in such a manner as to approach the protective film 1b. Then, the full-curing unit 44 is operated such that at least one of heating, application of active energy rays, or dehydration is applied to the protective film 1b. As a result, the protective film 1b enters a fully-cured state.

Note that the full-curing step S40 may be carried out with use of a curing apparatus having a structure different from that of the curing apparatus 40. For example, the full-curing step S40 may be carried out with use of a curing apparatus including a table capable of supporting the workpiece 11, a chamber for defining a space in which the table is present, and a full-curing unit capable of performing at least one of heating, application of active energy rays, or dehydration with respect to the space.

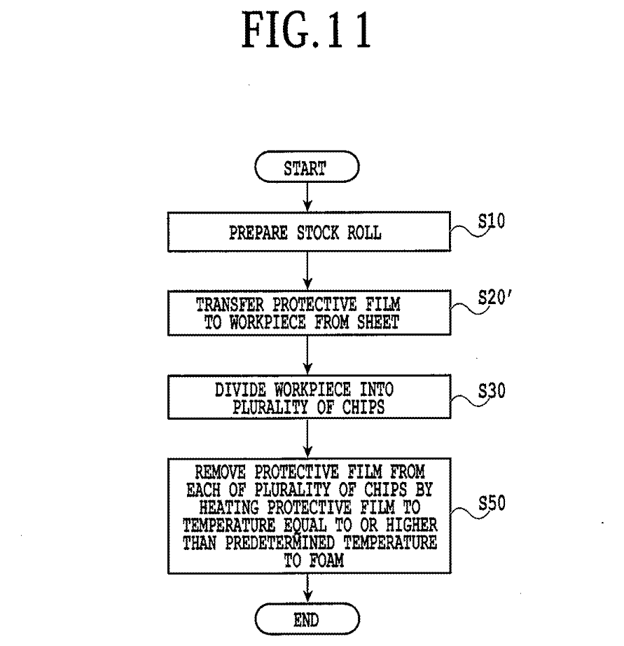

In addition, when the protective film 1b includes a thermal foaming agent that foams by being heated to a temperature equal to or higher than a predetermined temperature, the chip manufacturing method according to the present invention may include a removing step S50 of removing the protective film 1b from each of the plurality of chips by heating the protective film 1b to a temperature equal to or higher than the predetermined temperature to foam, after the dividing step S30 has been carried out, as illustrated in FIG. 11.

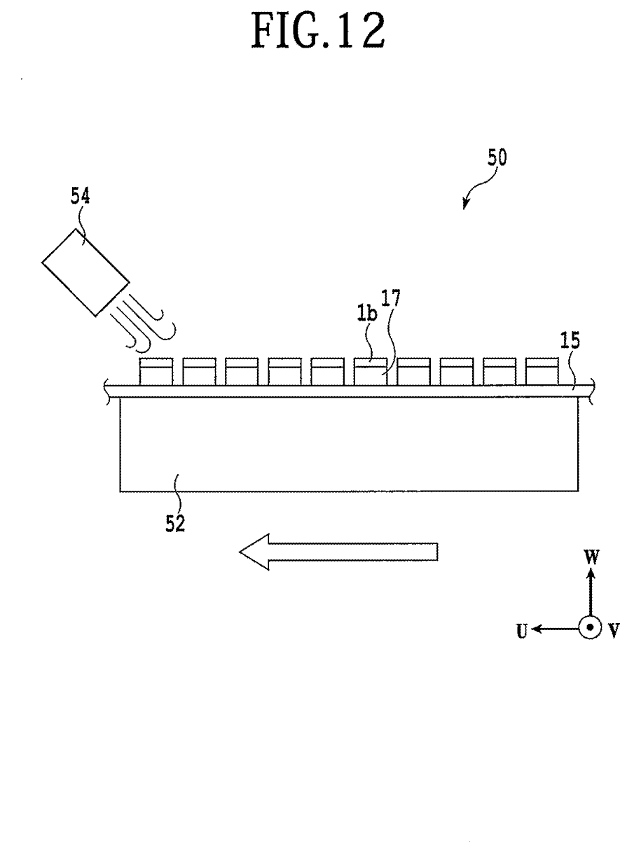

FIG. 12 is a side view schematically illustrating the manner of performing the removing step S50. Note that a direction (U direction) indicated by an arrow U and a direction (V direction) indicated by an arrow V illustrated in FIG. 12 are directions orthogonal to each other on a horizontal plane, and a direction (W direction) indicated by an arrow W is a direction (vertical direction) orthogonal to each of the U direction and the V direction.

The removing step S50 is carried out with use of a removing apparatus 50. The removing apparatus 50 includes a chuck table 52 for holding a plurality of chips 17 in each of which the protective film 1b remains, via a support member 15. The chuck table 52 has, for example, a structure similar to that of the chuck table 22 illustrated in FIG. 5, and can hold the plurality of chips 17 via the support member 15 by suction force acting thereon.

Further, the chuck table 52 is coupled to a U direction moving mechanism (not illustrated). The U direction moving mechanism includes, for example, a ball screw and a motor connected to the ball screw. When the U direction moving mechanism is operated, the chuck table 52 moves along the U direction in such a manner as to pass under an air curtain 54. The air curtain 54 extends along the V direction by a length greater than a length of the chuck table 52 in the V direction, and is capable of supplying hot air having a temperature equal to or higher than a predetermined temperature at which the thermal foaming agent included in the protective film 1b foams, toward an obliquely downward direction.

In performing the removing step S50 in the removing apparatus 50, first, the chuck table 52 is moved along the U direction in such a manner as to be separated from the air curtain 54. Next, the plurality of chips 17 are loaded to the chuck table 52 such that the protective film 1b faces upward. Subsequently, the plurality of chips 17 are held on the chuck table 52 via the support member 15.

Then, while hot air is being supplied from the air curtain 54, the chuck table 52 is moved along the U direction in such a manner that the plurality of chips 17 pass under the air curtain 54. As a result, the protective film 1b is heated to a temperature equal to or higher than the predetermined temperature to foam and be blown off from each of the chips 17. Consequently, the protective film 1b is removed from each of the plurality of chips 17.

Note that the removing step S50 may be carried out with use of a removing apparatus having a structure different from that of the removing apparatus 50. For example, the removing step S50 may be carried out with use of a removing apparatus in which a heater for causing the protective film 1b to foam and a blower for blowing off the protective film 1b from each of the chips 17 are provided separately from each other in place of the air curtain 54.

Further, the chip manufacturing method according to the present invention may be a chip manufacturing method in which the preparing step S10, the transferring step S20’, the full-curing step S40, the dividing step S30, and the removing step S50 are carried out in this order.

The structural and methodical details according to the above embodiment may be changed or modified without departing from the scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A stock roll for protective film transfer configured by a layered structure being wound, the layered structure including a sheet and a protective film applied to one surface of the sheet, wherein
the protective film is formed into a semi-cured state in which the protective film is able to be transferred to an object to be processed.

2. The stock roll for protective film transfer according to claim 1, wherein the protective film includes active energy ray curable resin or thermosetting resin.

3. The stock roll for protective film transfer according to claim 1, wherein the protective film includes a thermal foaming agent that foams by being heated to a temperature equal to or higher than a predetermined temperature.

4. The stock roll for protective film transfer according to claim 3, wherein the protective film includes active energy ray curable resin or thermosetting resin.

5. A protective film arranging method of arranging a protective film on an object to be processed, comprising:
applying a protective film forming agent in liquid form to one surface of a sheet;
forming the protective film forming agent applied to the one surface of the sheet into a protective film in a semi-cured state; and
transferring the protective film to the object to be processed, from the sheet.

6. The protective film arranging method according to claim 5, further comprising:
forming the protective film transferred to the object to be processed, into a fully-cured state.

7. A chip manufacturing method of manufacturing a plurality of chips by dividing a workpiece on which a plurality of devices are formed, along boundaries of the plurality of devices, comprising:
applying a protective film forming agent in liquid form to one surface of a sheet;
forming the protective film forming agent applied to the one surface of the sheet into a protective film in a semi-cured state;
transferring the protective film to the workpiece from the sheet; and
dividing the workpiece into the plurality of chips by processing the workpiece from a side where the protective film is arranged, along the boundaries of the plurality of devices.

8. The chip manufacturing method according to claim 7, wherein the protective film includes a thermal foaming agent that foams by being heated to a temperature equal to or higher than a predetermined temperature, and
removing the protective film from each of the plurality of chips by heating the protective film remaining in each of the plurality of chips to a temperature equal to or higher than the predetermined temperature to foam is further provided.

9. The chip manufacturing method according to claim 7, further comprising:
before dividing the workpiece into the plurality of chips, forming the protective film transferred to the workpiece into a fully-cured state.

10. The chip manufacturing method according to claim 9, wherein
the protective film includes a thermal foaming agent that foams by being heated to a temperature equal to or higher than a predetermined temperature, and
removing the protective film from each of the plurality of chips by heating the protective film remaining in each of the plurality of chips to a temperature equal to or higher than the predetermined temperature to foam is further provided.
